(19) United States
(12) Patent Application Publication
(10) Pub. No.: US 2025/0246436 A1
(43) Pub. Date: Jul. 31, 2025

(54) PLANARIZATION PROCESS AND METHOD

(71) Applicant: Taiwan Semiconductor Manufacturing Co., Ltd., Hsinchu (TW)

(72) Inventors: Chun-Yu Liu, New Taipei (TW); Jin-Hao Jhang, Chubei (TW); Ku-Feng Yang, Baoshan Township (TW); Szuya Liao, Zhubei (TW)

(21) Appl. No.: 18/646,459

(22) Filed: Apr. 25, 2024

Related U.S. Application Data
(60) Provisional application No. 63/626,323, filed on Jan. 29, 2024.

(51) Int. Cl. H01L 21/321; H01L 21/02; H01L 21/268; H01L 21/48

(52) U.S. Cl. CPC H01L 21/3212; H01L 21/02074; H01L 21/268; H01L 21/485

(57) ABSTRACT

A method includes forming a device layer on a first surface of a first substrate, forming a first interconnect structure over the device layer, depositing a bonding layer over the first interconnect structure, forming a diamond layer over the bonding layer, performing a laser treatment on a top portion of the diamond layer by applying laser energy to the top portion of the diamond layer using a laser beam, and performing a thinning process on the diamond layer to remove the top portion of the diamond layer.

### CROSS-REFERENCE TO RELATED APPLICATIONS

This application claims priority to U.S. Application No. 63/626,323, filed on Jan. 29, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 4 illustrate cross-sectional views of intermediate stages in the manufacturing of a semiconductor device, in accordance with some embodiments.

FIGS. 5A through 5C illustrate a laser treatment process, in accordance with some embodiments.

FIG. 5D illustrates a thinning process, in accordance with some embodiments.

FIGS. 6A and 6B illustrate a laser treatment process, in accordance with other embodiments.

FIGS. 6C and 6D illustrates a thinning process, in accordance with other embodiments.

FIG. 7 illustrates a cross-sectional view of a combined laser treatment and planarization apparatus, in accordance with some embodiments.

FIGS. 8 through 14 illustrate cross-sectional views of combined laser treatment and planarization apparatus, in accordance with other embodiments.

FIGS. 15 through 18 illustrate cross-sectional views of intermediate stages in the manufacturing of a semiconductor device, in accordance with some embodiments.

FIG. 19 illustrates a cross-sectional view of intermediate stages in the manufacturing of a semiconductor device, in accordance with other embodiments.

FIG. 20 illustrates a cross-sectional view of intermediate stages in the manufacturing of a semiconductor device, in accordance with other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods applied to the formation of a semiconductor device that includes forming a diamond layer over an active layer (also referred to as a device layer). A laser treatment is then performed in which laser energy is applied to the diamond layer using a laser beam to transform a top portion of the diamond layer into a graphite layer. In other embodiments, the laser treatment is used to modify the top portion of the diamond layer (e.g., to form a modified diamond layer). A planarization process that may include chemical mechanical planarization (CMP) is then performed to remove the graphite layer or the modified diamond layer and leave a remaining portion of the diamond layer over the active layer. The diamond layer may function as a heat dissipation layer. A semiconductor substrate may then be bonded to an opposite side of the remaining portion of the diamond layer as the active layer. Advantageous features of one or more embodiments may include allowing the removal of the top portion of the diamond layer (in the form of the graphite layer or the modified diamond layer) at higher polishing rates using the planarization process. In addition, the one or more embodiments, can be integrated with existing semiconductor manufacturing processes, which results in optimized efficiency and cost-effectiveness. Further, an improved surface roughness of the remaining portion of the diamond layer can be achieved after the planarization process is performed.

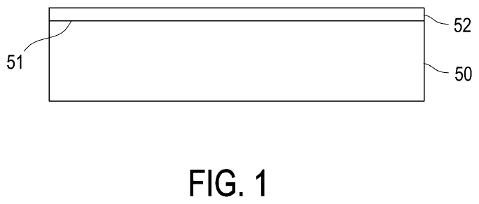

FIGS. 1-6D and 15-18 are cross-sectional views of intermediate stages in the manufacturing of a semiconductor device 10, in accordance with some embodiments.

FIG. 1 illustrates the formation of an active layer 52 (also referred to as a device layer) in and/or on a first surface 51 (also referred to as an active surface) of a substrate 50. The substrate 50 may comprise a carrier wafer, or the like. The substrate 50 may comprise a bulk semiconductor substrate, SOI substrate, multi-layered semiconductor substrate, or the like. The semiconductor material of the substrate 50 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaIlnP, and/or GaInAsP; or combinations thereof. Other substrates, such as multi-layered or gradient substrates, may also be used. The substrate 50 may be doped or undoped. The active layer 52 may comprise devices, such as transistors, capacitors, resistors, diodes, and the like, that are formed in and/or on the first surface 51 of the substrate 50.

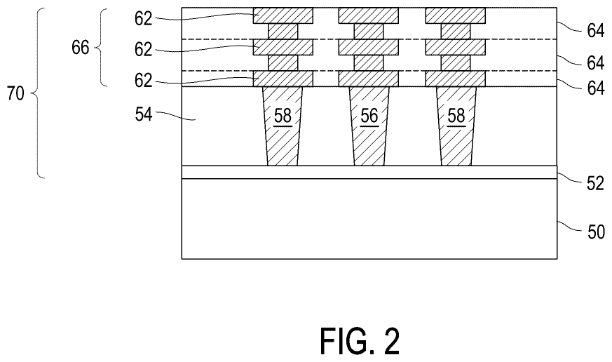

In FIG. 2, a dielectric layer 54 is formed over the active layer 52. In some embodiments, the dielectric layer 54 may comprise silicon nitride, silicon oxide, phospho-silicate glass (PSG), boro-silicate glass (BSG), boron-doped phospho-silicate glass (BPSG), undoped silicate glass (USG), silicon oxide, or the like, which may be deposited by any suitable method, such as CVD, ALD, plasma-enhanced chemical vapor deposition (PECVD), or the like.

Subsequently, contact vias (e.g., gate contacts 56 and source/drain vias 58) may be formed to contact one or more devices in and/or on the first surface 51 of the substrate 50. The source/drain vias 58 provide electrical connections to the source and drain regions of the one or more devices, facilitating the flow of charge carriers, while the gate contacts 56 allow for the controlled modulation of this flow by applying a voltage to each respective gate terminal. As an example to form the gate contacts 56 and the source/drain vias 58, openings for the gate contacts 56 and the source/drain vias 58 are formed through the dielectric layer 54. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the dielectric layer 54. The remaining liner and conductive material form the gate contacts 56 and the source/drain vias 58 in the openings. The gate contacts 56 and the source/drain vias 58 may be formed in distinct processes, or may be formed in the same process. Although shown as being formed in the same cross-section, it should be appreciated that each of the gate contacts 56 and the source/drain vias 58 may be formed in different cross-sections, which may avoid shorting of the contacts.

A front-side interconnect structure 66 is then formed on the dielectric layer 54, the gate contacts 56, and the source/drain vias 58. The front-side interconnect structure 66 includes dielectric layers 64 and layers of conductive features 62 in the dielectric layers 64. The dielectric layers 64 may include low-k dielectric layers formed of low-k dielectric materials. The dielectric layers 64 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 64 may also include polymer layers.

The conductive features 62 may include conductive lines and vias, which may be formed using damascene processes. The conductive features 62 may include metal lines and metal vias, which includes diffusion barriers and a copper containing material over the diffusion barriers. There may also be aluminum pads over and electrically connected to the metal lines and vias. The conductive features 62 may be electrically connected to the gate contacts 56 and the source/drain vias 58. The front-side interconnect structure 66, the gate contacts 56, the source/drain vias 58 and the dielectric layer 54 may be collectively referred to as a structure 70.

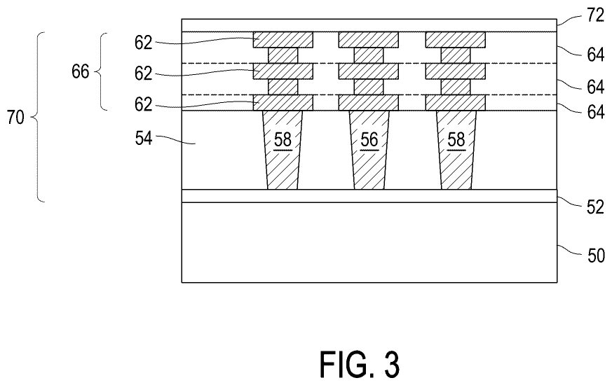

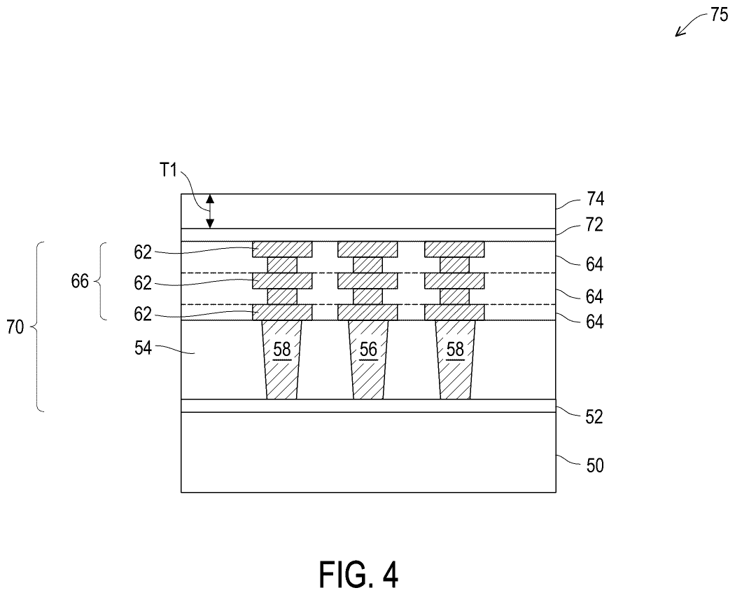

In FIG. 3, a bonding layer 72 may be deposited over the front-side interconnect structure 66 by any suitable process, such as physical vapor deposition (PVD), CVD, ALD, or the like. The bonding layer 72 may facilitate the bonding of the front-side interconnect structure 66 to a diamond layer 74 in subsequent processes (see FIG. 4). The bonding layer 72 may comprise a dielectric material such as silicon oxide (e.g., SiO₂), silicon nitride, or the like. In other embodiments, the bonding layer may comprise SiON, SiOC, SiOCN, SiC, AIO, AlN, TiO, or the like.

In FIG. 4, the diamond layer 74 is formed over the bonding layer 72 using for example, CVD, ALD, PECVD, or the like. The combination of the diamond layer 74, the bonding layer 72, the structure 70, and the substrate 50 may be referred to subsequently as the workpiece 75. In an embodiment, a thickness T1 of the diamond layer 74 may be in a range from 1 μm to 20 μm. The diamond layer 74 is a thermal conductor, and each carbon atom of the diamond layer 74 is tetrahedrally bonded to four other carbon atoms in a three-dimensional, covalent network structure. The carbon-carbon bonds in the diamond layer are strong covalent bonds, and each carbon atom is sp3 hybridized, forming a rigid and strong crystal lattice.

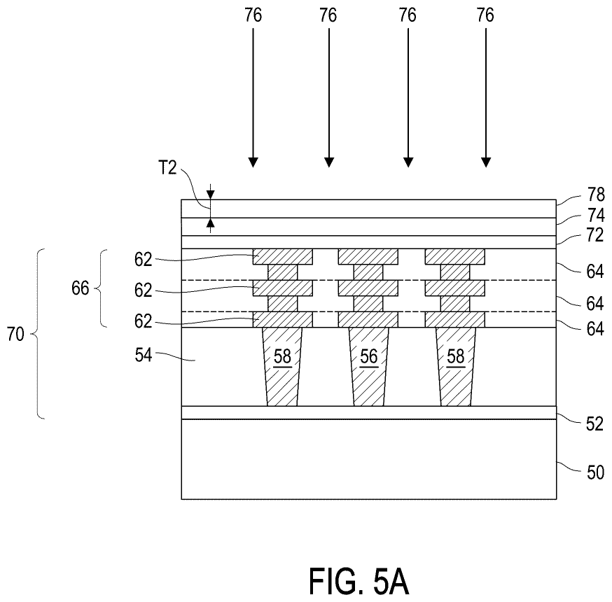

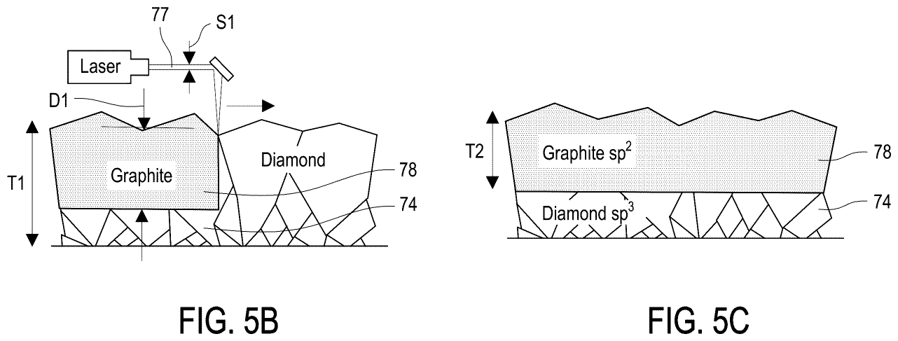

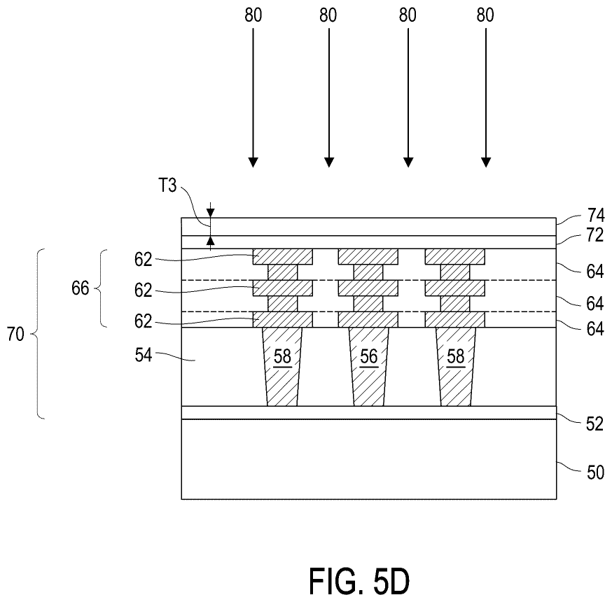

In FIGS. 5A-5C, a laser treatment 76 is performed during which laser energy is applied to the diamond layer 74 using a laser beam 77 to transform a top portion of the diamond layer 74 into a graphite layer 78. FIG. 5B illustrates a first region of the diamond layer 74 during the laser treatment 76. FIG. 5C illustrates the first region of the diamond layer 74 after the laser treatment 76 is performed. The laser treatment 76 may comprise a laser heat treatment process that employs the laser beam 77 (shown in FIG. 5B) that is generated from a laser source to heat the top portion of the diamond layer 74, and transform the top portion of the diamond layer 74 into the graphite layer 78. The laser beam 77 allows for selective heating of the diamond layer 74 by controlling laser parameters such as laser power, laser wavelength, laser focus depth, and laser spot size, in order to transform the top portion of the diamond layer 74 into the graphite layer 78. The graphite layer 78 comprises carbon atoms that are arranged in layers, with each carbon atom bonded to three others in a plane in a hexagonal pattern. The layers are held together by weak van der Waals forces. Within each layer, carbon-carbon bonds are strong covalent bonds, and each carbon atom is sp2 hybridized, creating a planar structure. The graphite material of the graphite layer 78 has a lower melting point and is softer than the diamond material of the diamond layer 74. This is advantageous as the softer graphite layer 78 can be more easily planarized than the diamond layer 74 using for example, a subsequent CMP process, or the like. In addition, after the planarization, an improved surface roughness of the remaining portion of the diamond layer 74 can be achieved. The laser treatment 76 may comprise systematically traversing (also referred to as scanning) a top surface of the diamond layer 74 with the laser beam 77 as shown in FIG. 5B, wherein the laser beam 77 follows a predetermined pattern. By controlling the laser power and laser focus depth of the laser beam 77, the top portion of the diamond layer 74 may be transformed into the graphite layer 78. After the laser treatment 76, the graphite layer 78 may have a thickness T2 (as shown in FIG. 5C). In an embodiment, the thickness T2 may be in a range from 200 nm to 10 μm, wherein the thickness T2 is less than the thickness T1. In an embodiment, the laser beam 77 may have a laser power that is in a range from 10 mJ/cm² to 10 J/cm². In an embodiment, the laser beam 77 may have a wavelength that is in a range from 10 nm to 5 μm. In an embodiment, the laser beam 77 may have a focus depth D1 (which may also be referred to as the depth of focus) that is in a range from 200 nm to 10 μm. In an embodiment, the focus depth D1 may be equal to the thickness T2. In an embodiment, a time in between consecutive laser pulses from the laser source that generates the laser beam 77 is in a range from 10 ps to 200 ns. In an embodiment, a diameter S1 of the laser beam 77 (also referred to as the spot size) is in a range from 150 nm to 10 μm. The laser treatment 76 may be performed at a pressure that is in a range from 1 torr to 760 torr.

In an embodiment, the laser treatment 76 may be performed more than once in a cyclical manner. In an embodiment, a first laser treatment 76 may be performed using the laser beam 77 having a first laser power, and a second laser treatment 76 using the laser beam 77 having a second laser power may be performed after the first laser treatment 76 is performed, wherein the first laser power is greater than the second laser power. Advantages can be achieved by performing the first laser treatment 76 using the laser beam 77 having the first laser power, and performing the second laser treatment 76 using the laser beam 77 having the second laser power after the first laser treatment 76 is performed, wherein the first laser power is greater than the second laser power. These include the first laser treatment 76 allowing for faster conversion of the top portion of the diamond layer 74 to the graphite layer 78 up to the desired thickness T2, while the second laser treatment 76 allows for the reduction of the roughness of a top surface of the remaining portion of the diamond layer 74 below the graphite layer 78.

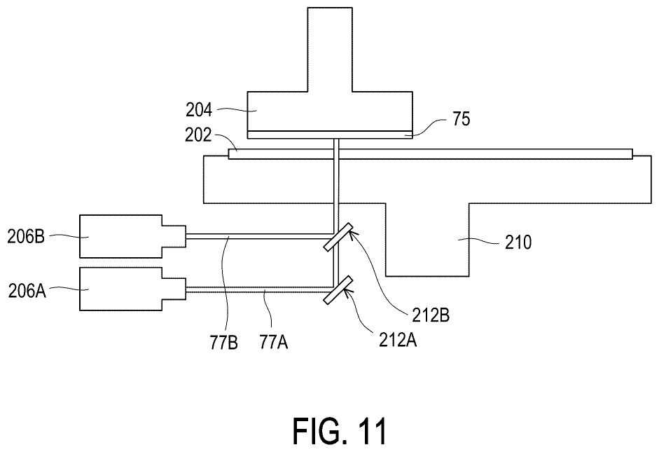

In an embodiment, a plurality of laser sources (e.g., laser sources 206A/B described subsequently in FIGS. 11-14) may be used to generate respective laser beams 77 that are scanned over the top surface of the diamond layer 74 during the laser treatment 76. The use of the plurality of laser beams 77 during the laser treatment 76 results in an increased scanning rate and faster transformation of the top portion of the diamond layer 74 into the graphite layer 78. In addition, the use of the plurality of laser beams 77 (e.g., through the tuning of the laser powers of respective laser beams 77) during the laser treatment 76 allows for a greater control of the roughness of the top surface of the remaining portion of the diamond layer 74 below the graphite layer 78.

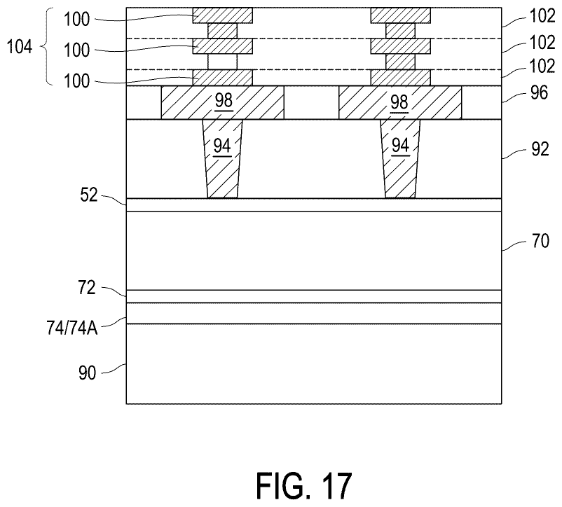

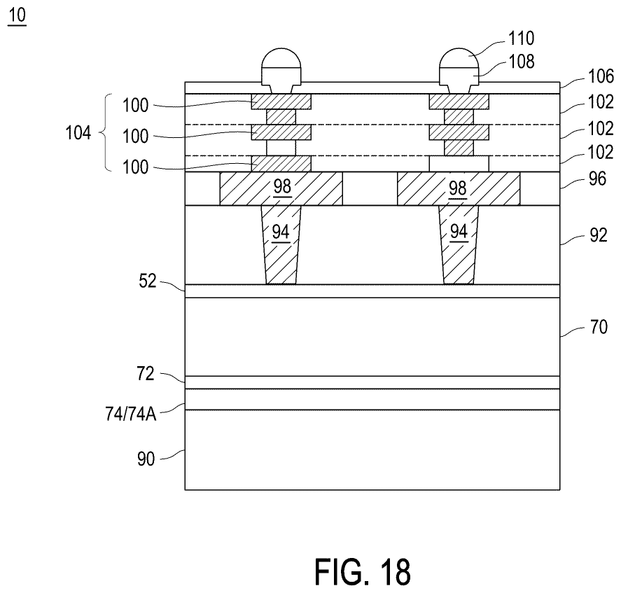

In FIG. 5D, a thinning process 80 is applied to a top surface of the graphite layer 78 in order to remove the graphite layer 78. The thinning process 80 may comprise a planarization process that is performed after the laser treatment 76 is performed. In an embodiment, the thinning process 80 may be performed at the same time as the laser treatment 76 is performed. The thinning process 80 may comprise a mechanical polishing process, a grinding process, a chemical mechanical planarization (CMP) process, a wet chemical removal process, a combination thereof, or the like. After the thinning process 80, a top surface of the remaining portion of the diamond layer 74 may be exposed. In an embodiment, after the thinning process 80 is performed, a thickness T3 of the remaining portion of the diamond layer 74 may be in a range from 100 nm to 10 μm. In an embodiment, after the thinning process 80, an average deviation in height of the features of the top surface of the remaining portion of the diamond layer 74 from the mean plane over a given area of the diamond layer 74 (also referred to as the surface roughness) is less than 50 nm. The remaining portion of the diamond layer 74 may function as a heat dissipation layer that is used to effectively dissipate the heat generated in the active layer 52 and subsequently formed conductive lines 98 (shown in FIG. 17). Advantages can be achieved by performing the thinning process 80 after or during performing the laser treatment 76 in order to remove the graphite layer 78 such that the thickness T3 of the remaining portion of the diamond layer 74 is in the range from 100 nm to 10 μm. These advantages include reducing stress concentrations within the semiconductor device 10 (shown subsequently in FIG. 18). As a result, a risk of cracking of the semiconductor device 10 due to these stress concentrations is reduced, leading to improved reliability and robustness of the semiconductor device 10.

In an embodiment, the combination of the laser treatment 76 and the thinning process 80 may be performed cyclically until a desired thickness T3 and surface roughness of the remaining portion of the diamond layer 74 is achieved. A plurality of iterations of the laser treatment 76 followed by the thinning process 80 may be performed in order to optimize the thickness of the remaining portion of the diamond layer 74, and in order to control the roughness of the top surface of the remaining portion of the diamond layer 74.

Advantages can be achieved by performing the laser treatment 76 during which laser energy is applied to the diamond layer 74 using the laser beam 77 to transform the top portion of the diamond layer 74 into the graphite layer 78. After or during the laser treatment 76, the thinning process 80 is applied to the top surface of the graphite layer 78 in order to remove the graphite layer 78, such that a thickness T3 of the remaining portion of the diamond layer 74 after the thinning process 80 is performed may be in a range from 100 nm to 10 μm. The remaining portion of the diamond layer 74 may function as a heat dissipation layer that is used to effectively dissipate the heat generated in the active layer 52 and subsequently formed conductive lines 98 (shown in FIG. 17). These advantages include allowing the removal of the graphite layer 78 at higher polishing rates using the thinning process 80. In addition, the laser treatment 76 and the thinning process 80 can be integrated with existing semiconductor manufacturing processes, which results in optimized efficiency and cost-effectiveness. Further, an improved surface roughness of the remaining portion of the diamond layer 74 can be achieved after the thinning process 80 is performed.

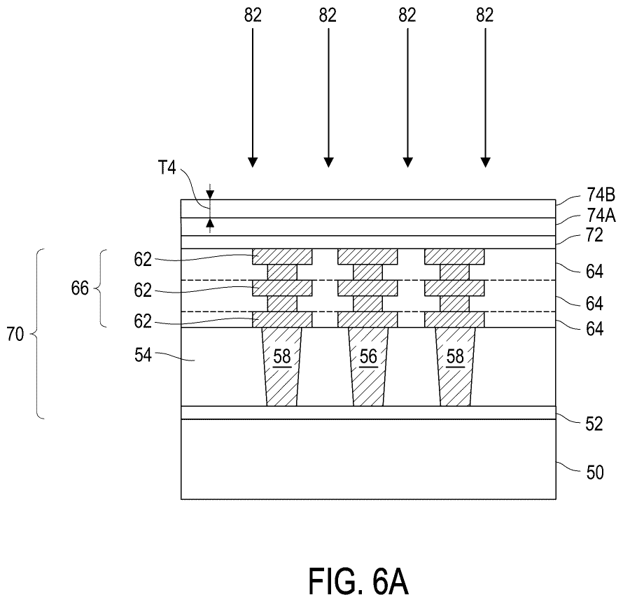

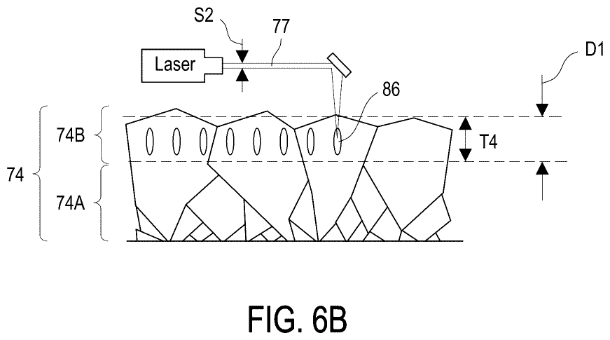

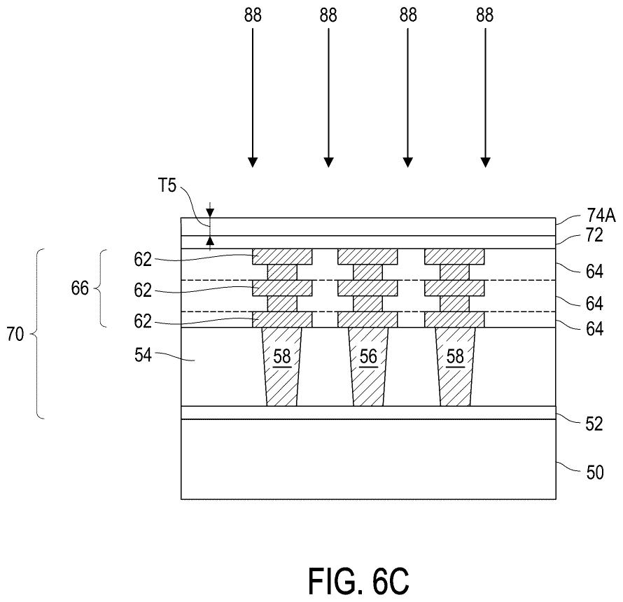

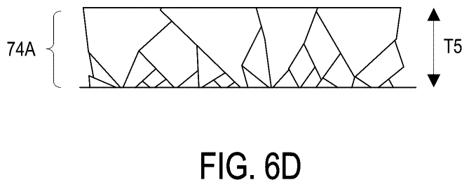

FIGS. 6A-6D illustrate an alternative embodiment. Unless specified otherwise, like reference numerals in this embodiment (and subsequently discussed embodiments) represent like components in the embodiment shown in FIGS. 1-5D formed by like processes. Accordingly, the process steps and applicable materials may not be repeated herein. The initial steps of this embodiment are essentially the same as shown in FIGS. 1 through 4.

In FIGS. 6A-6B, a laser treatment 82 is performed during which laser energy is applied to the diamond layer 74 using the laser beam 77 to modify a top portion of the diamond layer 74B and induce the formation of defects and cracks 86 within the top portion of the diamond layer 74B. FIG. 6B illustrates a first region of the diamond layer 74 during the laser treatment 82. The laser treatment 82 may comprise a laser heat treatment process during which the material of the diamond layer 74 absorbs multiple photons simultaneously through the use of the laser beam 77. During the laser treatment 82, a focal point of the laser beam 77 is placed within the top portion of the diamond layer 74B, and the focal point is the region where a laser intensity of the laser beam 77 is maximized, and the energy is concentrated. As a result, defects and cracks 86 may be induced that propagate from a top surface of the top portion of the diamond layer 74B and that extend through the top portion of the diamond layer 74B. After the laser treatment 82, the top portion of the diamond layer 74B remains as a sp3 hybridized crystal lattice. The bottom portion of the diamond layer 74A that is disposed below the top portion of the diamond layer 74B remains undamaged and unaffected (e.g., no defects or cracks 86 are induced in the bottom portion of the diamond layer 74A) by the laser treatment 82 since the focal point of the laser beam 77 is not placed within the bottom portion of the diamond layer 74A. The laser beam 77 allows for the inducing of defects and cracks 86 within the top portion of the diamond layer 74B by controlling laser parameters such as laser power, laser focus depth, and laser spot size, in order to modify the top portion of the diamond layer 74B. Modifying the top portion of the diamond layer 74B to induce the defects and cracks 86 has advantages, as the modified top portion of the diamond layer 74B can be more easily planarized (e.g., due to its fractured nature) than the unmodified bottom portion of the diamond layer 74A using for example, a subsequent CMP process, or the like. In addition, after the planarization, an improved surface roughness of the unmodified bottom portion of the diamond layer 74A can be achieved. The laser treatment 82 may comprise systematically traversing (also referred to as scanning) a top surface of the diamond layer 74 with the laser beam 77 as shown in FIG. 6B, wherein the laser beam 77 follows a predetermined pattern. By controlling the laser power, the laser focus depth, and the spot size of the laser beam 77, the top portion of the diamond layer 74B may be modified by inducing defects and cracks 86 into the top portion of the diamond layer 74B.

After the laser treatment 82, the top portion of the diamond layer 74B may have a thickness T4 (as shown in FIG. 6B). In an embodiment, the thickness T4 may be in a range from 200 nm to 10 μm, wherein the thickness T4 is less than the thickness T1. In an embodiment, the laser beam 77 may have a laser power that is in a range from 10 mJ/cm² to 10 J/cm²In an embodiment, the laser beam 77 may have a wavelength that is in a range from 10 nm to 5 μm. In an embodiment, the laser beam 77 may have a focus depth D1 (which may also be referred to as the depth of focus) that is in a range from 200 nm to 10 μm. In an embodiment, the focus depth D1 may be equal to the thickness T4. In an embodiment, a time in between consecutive laser pulses from the laser source that generates the laser beam 77 is in a range from 10 ps to 200 ns. In an embodiment, a diameter S2 of the laser beam 77 (also referred to as the spot size) is in a range from 100 nm to 3 μm. The laser beam 77 having the diameter S2 in the range from 100 nm to 3 μm may have advantages. These advantages include the smaller diameter S2 of the laser beam 77 allowing for an increase in energy concentration of the laser beam 77, which results in increased defect and crack 86 induction in the top portion of the diamond layer 74B. The laser treatment 82 may be performed at a pressure that is in a range from 1 torr to 760 torr.

In an embodiment, the laser treatment 82 may be performed more than once in a cyclical manner. In an embodiment, a plurality of laser sources (e.g., laser sources 206A/B described subsequently in FIGS. 11-14) may be used to generate respective laser beams 77 that are scanned over the top surface of the diamond layer 74 during the laser treatment 82. The use of the plurality of laser beams 77 during the laser treatment 82 results in an increased scanning rate and faster modification of the top portion of the diamond layer 74B by inducing of the defects and cracks 86 in the top portion of the diamond layer 74B.

In FIG. 6C, a thinning process 88 is applied to a top surface of the top portion of the diamond layer 74B in order to remove the top portion of the diamond layer 74B. FIG. 6D illustrates the first region of the diamond layer 74 after the thinning process 88 is performed. The thinning process 88 may comprise a planarization process that may be performed after the laser treatment 82 is performed. In an embodiment, the thinning process 88 may be performed at the same time as the laser treatment 82. The thinning process 88 may comprise a mechanical polishing process, a grinding process, a chemical mechanical planarization (CMP) process, a wet chemical removal process, a combination thereof, or the like. After the thinning process 88, a top surface of the bottom portion of the diamond layer 74A may be exposed. In an embodiment, after the thinning process 88 is performed, a thickness T5 of the bottom portion of the diamond layer 74A may be in a range from 100 nm to 10 μm. In an embodiment, after the thinning process 88, an average deviation in height of the features of the top surface of the bottom portion of the diamond layer 74A from the mean plane over a given area of the bottom portion of the diamond layer 74A (also referred to as the surface roughness) is less than 50 nm. The bottom portion of the diamond layer 74A may function as a heat dissipation layer that is used to effectively dissipate the heat generated in the active layer 52 and the subsequently formed conductive lines 98 (shown in FIG. 17). Advantages can be achieved by performing the thinning process 88 during or after performing the laser treatment 82 in order to remove the top portion of the diamond layer 74B such that the thickness T5 of the bottom portion of the diamond layer 74A is in the range from 100 nm to 10 μm. These advantages include reducing stress concentrations within the semiconductor device 10 (shown subsequently in FIG. 18). As a result, a risk of cracking of the semiconductor device 10 due to these stress concentrations is reduced, leading to improved reliability and robustness of the semiconductor device 10.

In an embodiment, the combination of the laser treatment 82 and the thinning process 88 may be performed cyclically until a desired thickness T5 and surface roughness of the bottom portion of the diamond layer 74A is achieved. A plurality of iterations of the laser treatment 82 followed by the thinning process 88 may be performed in order to optimize the thickness T5 of the bottom portion of the diamond layer 74A, and in order to control the roughness of the top surface of the bottom portion of the diamond layer 74A.

Advantages can be achieved by performing the laser treatment 82 during which laser energy is applied to the diamond layer 74 using the laser beam 77 to modify the top portion of the diamond layer 74B and induce the formation of defects and cracks 86 within the top portion of the diamond layer 74B. After or during the laser treatment 82, the thinning process 88 is applied to the top portion of the diamond layer 74B in order to remove the top portion of the diamond layer 74B, such that a thickness T5 of the bottom portion of the diamond layer 74A may be in a range from 100 nm to 10 μm. The bottom portion of the diamond layer 74A may function as a heat dissipation layer that is used to effectively dissipate the heat generated in the active layer 52 and subsequently formed conductive lines 98 (shown in FIG. 17). These advantages include allowing the removal of the modified top portion of the diamond layer 74B at higher polishing rates using the thinning process 88. In addition, the laser treatment 82 and the thinning process 88 can be integrated with existing semiconductor manufacturing processes, which results in optimized efficiency and cost-effectiveness. Further, an improved surface roughness of the bottom portion of the diamond layer 74A can be achieved after the thinning process 88 is performed.

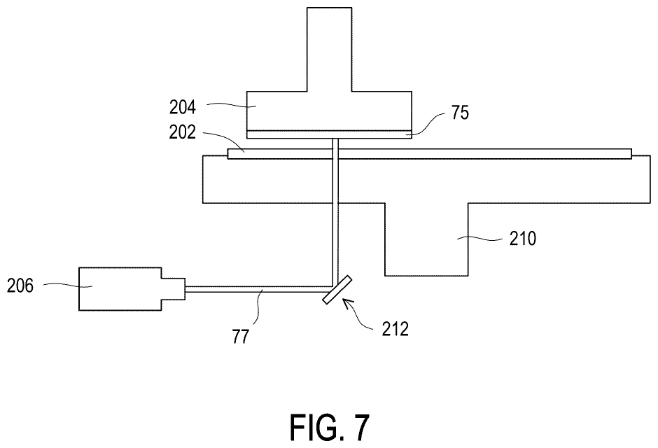

FIG. 7 shows a cross-sectional view of a combined laser treatment and planarization apparatus 12 that is used to perform the laser treatment 76, the laser treatment 82, the thinning process 80, and the thinning process 88 that were described previously in FIGS. 1 through 6D. The combined laser treatment and planarization apparatus 12 may comprise a polishing pad 202 that is disposed on and affixed to a top surface of a platen 210. In an embodiment, the platen 210 may be rotatable. The workpiece 75 (described previously in FIG. 4 which may comprise the combination of the diamond layer 74, the bonding layer 72, the structure 70, and the substrate 50) that is to undergo one or more of the laser treatment 76, the laser treatment 82, the thinning process 80, and the thinning process 88 is disposed on a bottom surface of a rotatable support 204 such that the workpiece 75 and the polishing pad 202 are facing each other. In an embodiment, the rotatable support 204 is disposed vertically above the platen 210. A vacuum system may be used to secure the workpiece 75 to the rotatable support 204, ensuring it remains in place during processing. The rotatable support 204 is capable of motion along three orthogonal axes (e.g., the x-axis, y-axis, and z-axis). In an embodiment, a diameter of the platen 210 may be greater than a diameter of the rotatable support 204.

The combined laser treatment and planarization apparatus 12 may comprise a laser source 206 disposed below or on a side of the platen 210 that generates the laser beam 77 that is used to perform the laser treatment 76 and/or the laser treatment 82 on the workpiece 75 as described previously in FIGS. 5A through 6D. The combined laser treatment and planarization apparatus 12 may comprise a galvanometer mirror 212 that is used to assist in the scanning by the laser beam 77 of the workpiece 75. By controlling the current in the galvanometer, the mirror 212 can be precisely positioned to direct the laser beam 77.

Each of the platen 210 and the polishing pad 202 may comprise a hole that extends vertically through the respective platen 210 and the polishing pad 202 through which the laser beam 77 can be directed by the galvanometer mirror 212, and then on to the diamond layer 74 of the workpiece 75 to perform the laser treatment 76 and/or the laser treatment 82 that were described previously in FIGS. 5A through 6D. In an embodiment, the platen 210 and the polishing pad 202 may comprise transparent portions through which the laser beam 77 can be directed by the galvanometer mirror 212, and then on to the diamond layer 74 of the workpiece 75 to perform the laser treatment 76 and/or the laser treatment 82 that were described previously in FIGS. 5A through 6D. The transparent portions of the platen 210 and the polishing pad 202 may comprise thermoplastic polyurethane, or the like. The scanning of the laser beam 77 on the workpiece 75 is performed by moving the rotatable support 204 along a pre-determined path.

To perform the thinning process 80 and/or the thinning process 88 (e.g. when the thinning process 80 and the thinning process 88 comprise a CMP process), the rotatable support 204 is moved vertically towards the platen 210 until the polishing pad 202 and the workpiece 75 are in physical contact. Due to the rotational action of the rotatable support 204, the workpiece 75 rotates against the polishing pad 202 which results in the abrasion of materials of the workpiece 75 (e.g., the top portion of the diamond layer 74B as shown in FIG. 6C or the graphite layer 78 as shown in FIG. 5D). In an embodiment, a chemical slurry that may contain abrasive particles and/or chemical agents may be utilized during the thinning process 80 and/or the thinning process 88 to facilitate material removal. In an embodiment, the laser treatment 76 and the thinning process 80 may be performed simultaneously using the combined laser treatment and planarization apparatus 12. In an embodiment, the thinning process 80 is performed using the combined laser treatment and planarization apparatus 12 after the laser treatment 76 is performed using the combined laser treatment and planarization apparatus 12. In an embodiment, the laser treatment 82 and the thinning process 88 may be performed simultaneously using the combined laser treatment and planarization apparatus 12. In an embodiment, the thinning process 88 is performed using the combined laser treatment and planarization apparatus 12 after the laser treatment 82 is performed using the combined laser treatment and planarization apparatus 12.

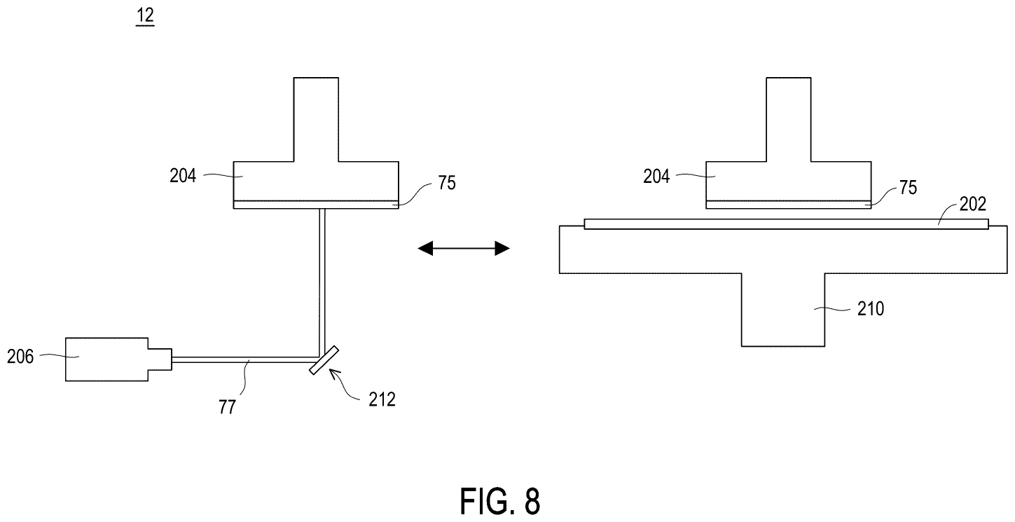

FIG. 8 illustrates a cross-sectional view of the combined laser treatment and planarization apparatus 12 in accordance with some other embodiments. Unless specified otherwise, like reference numerals in this embodiment (and subsequently discussed embodiments) represent like components in the embodiment shown in FIGS. 1 through 7 formed by like processes. Accordingly, the process steps and applicable materials may not be repeated herein.

In FIG. 8, the thinning process 80 may be performed using the combined laser treatment and planarization apparatus 12 after the laser treatment 76 is performed using the combined laser treatment and planarization apparatus 12. Further, the thinning process 88 may be performed using the combined laser treatment and planarization apparatus 12 after the laser treatment 82 is performed using the combined laser treatment and planarization apparatus 12.

The combined laser treatment and planarization apparatus 12 may comprise the laser source 206 disposed on a side of the platen 210, wherein the laser source 206 generates the laser beam 77 that is used to perform the laser treatment 76 and/or the laser treatment 82 on the workpiece 75 as described previously in FIGS. 5A through 6D. In an embodiment, the laser source 206 that generates the laser beam 77 may be disposed on a different platform to the rotatable support 204 and the platen 210. The combined laser treatment and planarization apparatus 12 may comprise a galvanometer mirror 212 that is used to assist in the scanning by the laser beam 77 of the workpiece 75. By controlling the current in the galvanometer, the mirror 212 can be precisely positioned to direct the laser beam 77. The rotatable support 204 with the workpiece 75 disposed on it may be positioned on a side of the platen 210 (e.g., not vertically above the platen 210), and the galvanometer mirror 212 may be used to direct the laser beam 77 on to the diamond layer 74 of the workpiece 75 to perform the laser treatment 76 and/or the laser treatment 82 that were described previously in FIGS. 5A through 6D. The scanning of the laser beam 77 on the workpiece 75 is performed by moving the rotatable support 204 along a pre-determined path. Therefore, the laser beam 77 is not directed through the platen 210 and the polishing pad 202 during the laser treatment 76 and the laser treatment 82 as was described previously in FIG. 7.

To perform the thinning process 80 and/or the thinning process 88 (e.g. when the thinning process 80 and the thinning process 88 comprise a CMP process), the rotatable support 204 is positioned vertically above the platen 210. The rotatable support 204 is then moved towards the platen 210 until the polishing pad 202 and the workpiece 75 are in physical contact. Due to the rotational action of the rotatable support 204, the workpiece 75 rotates against the polishing pad 202 which results in the abrasion of materials of the workpiece 75 (e.g., the top portion of the diamond layer 74B as shown in FIG. 6C or the graphite layer 78 as shown in FIG. 5D). In an embodiment, a chemical slurry that may contain abrasive particles and/or chemical agents may be utilized during the thinning process 80 and/or the thinning process 88 to facilitate material removal.

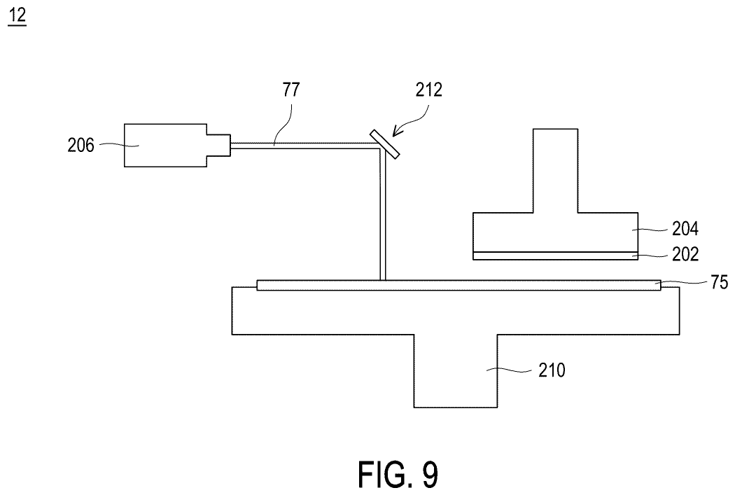

FIG. 9 illustrates a cross-sectional view of the combined laser treatment and planarization apparatus 12 in accordance with some other embodiments. Unless specified otherwise, like reference numerals in this embodiment (and subsequently discussed embodiments) represent like components in the embodiment shown in FIGS. 1 through 8 formed by like processes. Accordingly, the process steps and applicable materials may not be repeated herein.

The combined laser treatment and planarization apparatus 12 shown in FIG. 9 may be used to perform the laser treatment 76, the laser treatment 82, the thinning process 80, and the thinning process 88 that were described previously in FIGS. 1 through 6D. The combined laser treatment and planarization apparatus 12 may comprise the polishing pad 202 that is disposed on and affixed to a bottom surface of the rotatable support 204. The workpiece 75 (described previously in FIG. 4 which may comprise the combination of the diamond layer 74, the bonding layer 72, the structure 70, and the substrate 50) that is to undergo one or more of the laser treatment 76, the laser treatment 82, the thinning process 80, and the thinning process 88 is disposed on a top surface of the platen 210 such that the workpiece 75 and the polishing pad 202 are facing each other. In an embodiment, the platen 210 is rotatable. In an embodiment, the rotatable support 204 is disposed vertically above the platen 210. A vacuum system may be used to secure the workpiece 75 to the platen 210, ensuring it remains in place during processing. The rotatable support 204 is capable of motion along three orthogonal axes (e.g., the x-axis, y-axis, and z-axis). In an embodiment, a diameter of the platen 210 may be greater than a diameter of the rotatable support 204.

The combined laser treatment and planarization apparatus 12 may comprise the laser source 206 disposed above the platen 210 and on a side of the rotatable support 204, wherein the laser source 206 generates the laser beam 77 that is used to perform the laser treatment 76 and/or the laser treatment 82 on the workpiece 75 as described previously in FIGS. 5A through 6D. The combined laser treatment and planarization apparatus 12 may comprise the galvanometer mirror 212 that is used to assist in the scanning by the laser beam 77 of the workpiece 75. By controlling the current in the galvanometer, the mirror 212 can be precisely positioned to direct the laser beam 77 on to the diamond layer 74 of the workpiece 75 to perform the laser treatment 76 and/or the laser treatment 82 that were described previously in FIGS. 5A through 6D. In addition, the platen 210 may be rotated during the laser treatment 76 and/or the laser treatment 82.

To perform the thinning process 80 and/or the thinning process 88 (e.g. when the thinning process 80 and the thinning process 88 comprise a CMP process), the rotatable support 204 is moved vertically towards the platen 210 until the polishing pad 202 and the workpiece 75 are in physical contact. Due to the rotational action of the rotatable support 204 and/or the platen 210, the workpiece 75 rotates against the polishing pad 202 which results in the abrasion of materials of the workpiece 75 (e.g., the top portion of the diamond layer 74B as shown in FIG. 6C or the graphite layer 78 as shown in FIG. 5D). In an embodiment, a chemical slurry that may contain abrasive particles and/or chemical agents may be utilized during the thinning process 80 and/or the thinning process 88 to facilitate material removal. In an embodiment, the laser treatment 76 and the thinning process 80 may be performed simultaneously using the combined laser treatment and planarization apparatus 12. In an embodiment, the thinning process 80 is performed using the combined laser treatment and planarization apparatus 12 after the laser treatment 76 is performed using the combined laser treatment and planarization apparatus 12. In an embodiment, the laser treatment 82 and the thinning process 88 may be performed simultaneously using the combined laser treatment and planarization apparatus 12. In an embodiment, the thinning process 88 is performed using the combined laser treatment and planarization apparatus 12 after the laser treatment 82 is performed using the combined laser treatment and planarization apparatus 12.

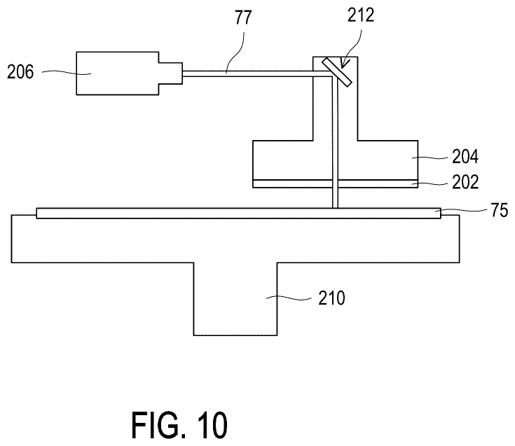

FIG. 10 illustrates a cross-sectional view of the combined laser treatment and planarization apparatus 12 in accordance with some other embodiments. Unless specified otherwise, like reference numerals in this embodiment (and subsequently discussed embodiments) represent like components in the embodiment shown in FIGS. 1 through 9 formed by like processes. Accordingly, the process steps and applicable materials may not be repeated herein.

The combined laser treatment and planarization apparatus 12 shown in FIG. 10 may be used to perform the laser treatment 76, the laser treatment 82, the thinning process 80, and the thinning process 88 that were described previously in FIGS. 1 through 6D. The combined laser treatment and planarization apparatus 12 may comprise the polishing pad 202 that is disposed on and affixed to a bottom surface of the rotatable support 204. The workpiece 75 (described previously in FIG. 4 which may comprise the combination of the diamond layer 74, the bonding layer 72, the structure 70, and the substrate 50) that is to undergo one or more of the laser treatment 76, the laser treatment 82, the thinning process 80, and the thinning process 88 is disposed on a top surface of the platen 210 such that the workpiece 75 and the polishing pad 202 are facing each other. In an embodiment, the platen 210 is rotatable. In an embodiment, the rotatable support 204 is disposed vertically above the platen 210. A vacuum system may be used to secure the workpiece 75 to the platen 210, ensuring it remains in place during processing. The rotatable support 204 is capable of motion along three orthogonal axes (e.g., the x-axis, y-axis, and z-axis). In an embodiment, a diameter of the platen 210 may be greater than a diameter of the rotatable support 204.

The combined laser treatment and planarization apparatus 12 may comprise the laser source 206 disposed above the platen 210 and on a side of the rotatable support 204, wherein the laser source 206 generates the laser beam 77 that is used to perform the laser treatment 76 and/or the laser treatment 82 on the workpiece 75 as described previously in FIGS. 5A through 6D. The combined laser treatment and planarization apparatus 12 may comprise the galvanometer mirror 212 that is used to assist in the scanning by the laser beam 77 of the workpiece 75. By controlling the current in the galvanometer, the mirror 212 can be precisely positioned to direct the laser beam 77. The galvanometer mirror 212 may be disposed within the structure of the rotatable support 204.

Each of the rotatable support 204 and the polishing pad 202 may comprise a hole that extends vertically through the respective rotatable support 204 and the polishing pad 202 through which the laser beam 77 can be directed by the galvanometer mirror 212, and then on to the diamond layer 74 of the workpiece 75 to perform the laser treatment 76 and/or the laser treatment 82 that were described previously in FIGS. 5A through 6D. In an embodiment, the hole that extends through the rotatable support 204 may extend vertically through a center of the rotatable support 204. In an embodiment, the rotatable support 204 and the polishing pad 202 may comprise transparent portions through which the laser beam 77 can be directed by the galvanometer mirror 212, and then on to the diamond layer 74 of the workpiece 75 to perform the laser treatment 76 and/or the laser treatment 82 that were described previously in FIGS. 5A through 6D. The transparent portions of the rotatable support 204 and the polishing pad 202 may comprise thermoplastic polyurethane, or the like. In an embodiment, the platen 210 may be rotated during the laser treatment 76 and/or the laser treatment 82.

To perform the thinning process 80 and/or the thinning process 88 (e.g. when the thinning process 80 and the thinning process 88 comprise a CMP process), the rotatable support 204 is moved vertically towards the platen 210 until the polishing pad 202 and the workpiece 75 are in physical contact. Due to the rotational action of the rotatable support 204 and/or the platen 210, the workpiece 75 rotates against the polishing pad 202 which results in the abrasion of materials of the workpiece 75 (e.g., the top portion of the diamond layer 74B as shown in FIG. 6C or the graphite layer 78 as shown in FIG. 5D). In an embodiment, a chemical slurry that may contain abrasive particles and/or chemical agents may be utilized during the thinning process 80 and/or the thinning process 88 to facilitate material removal. In an embodiment, the laser treatment 76 and the thinning process 80 may be performed simultaneously using the combined laser treatment and planarization apparatus 12. In an embodiment, the thinning process 80 is performed using the combined laser treatment and planarization apparatus 12 after the laser treatment 76 is performed using the combined laser treatment and planarization apparatus 12. In an embodiment, the laser treatment 82 and the thinning process 88 may be performed simultaneously using the combined laser treatment and planarization apparatus 12. In an embodiment, the thinning process 88 is performed using the combined laser treatment and planarization apparatus 12 after the laser treatment 82 is performed using the combined laser treatment and planarization apparatus 12.

FIG. 11 illustrates a cross-sectional view of the combined laser treatment and planarization apparatus 12 in accordance with some other embodiments. Unless specified otherwise, like reference numerals in this embodiment (and subsequently discussed embodiments) represent like components in the embodiment shown in FIGS. 1 through 10 formed by like processes. Accordingly, the process steps and applicable materials may not be repeated herein.

The combined laser treatment and planarization apparatus 12 of the embodiment shown in FIG. 11 may be similar to the combined laser treatment and planarization apparatus 12 of the embodiment shown in FIG. 7, except that the combined laser treatment and planarization apparatus 12 of the embodiment shown in FIG. 11 comprises a plurality of laser sources 206 (e.g., the laser sources 206A and 206B) that each generate a laser beam 77 (e.g., the laser beam 77A generated from the laser source 206A, and the laser beam 77B generated from the laser source 206B). The laser beam 77A and laser beam 77B may be used to perform the laser treatment 76 and/or the laser treatment 82 on the workpiece 75 as described previously in FIGS. 5A through 6D. Each of the platen 210 and the polishing pad 202 may comprise a hole that extends vertically through the respective platen 210 and the polishing pad 202 through which the laser beam 77A and the laser beam 77B can be directed by a galvanometer mirror 212A and a galvanometer mirror 212B, respectively, and then on to the diamond layer 74 of the workpiece 75 to perform the laser treatment 76 and/or the laser treatment 82 that were described previously in FIGS. 5A through 6D. In an embodiment, the platen 210 and the polishing pad 202 may comprise transparent portions through which the laser beam 77A and the laser beam 77B can be directed by the galvanometer mirror 212A and the galvanometer mirror 212B, respectively, and then on to the diamond layer 74 of the workpiece 75 to perform the laser treatment 76 and/or the laser treatment 82 that were described previously in FIGS. 5A through 6D. The transparent portions of the platen 210 and the polishing pad 202 may comprise thermoplastic polyurethane, or the like.

In an embodiment, the laser source 206A may have a higher laser power than the laser source 206B. In an embodiment, the laser source 206A may generate the laser beam 77A having a shorter wavelength than a wavelength of the laser beam 77B that is generated by the laser source 206B. Advantages can be achieved by the laser beam 77A having a shorter wavelength than the laser beam 77B. These include the laser beam 77A having a better transformation efficiency than the laser beam 77B which allows the energy from the laser beam 77A to be absorbed more easily by the diamond layer 74 in order to form the graphite layer 78 (shown in FIG. 5A). In addition, the energy from the laser beam 77A is also absorbed more easily by the diamond layer 74 to form the modified top portion of the diamond layer 74B (shown in FIG. 6A) at a faster rate to a required depth. Further, the use of the laser beam 77B having a longer wavelength may result in an improved surface roughness of the top surface of the remaining portion of the diamond layer 74 (as shown in FIG. 5D) after the thinning process 80, or an improved surface roughness of the top surface of the bottom portion of the diamond layer 74A (as shown in FIG. 6C) after the thinning process 88.

In an embodiment, during the laser treatment 76 and/or the laser treatment 82, the laser beam 77A and the laser beam 77B may be generated sequentially (e.g., at different times). In an embodiment, during the laser treatment 76 and/or the laser treatment 82, wherein the laser beam 77A has a different focus depth from the laser beam 77B, the laser beam 77A and the laser beam 77B may be generated simultaneously. In an embodiment, the laser treatment 76 and the thinning process 80 may be performed simultaneously using the combined laser treatment and planarization apparatus 12. In an embodiment, the laser treatment 82 and the thinning process 88 may be performed simultaneously using the combined laser treatment and planarization apparatus 12.

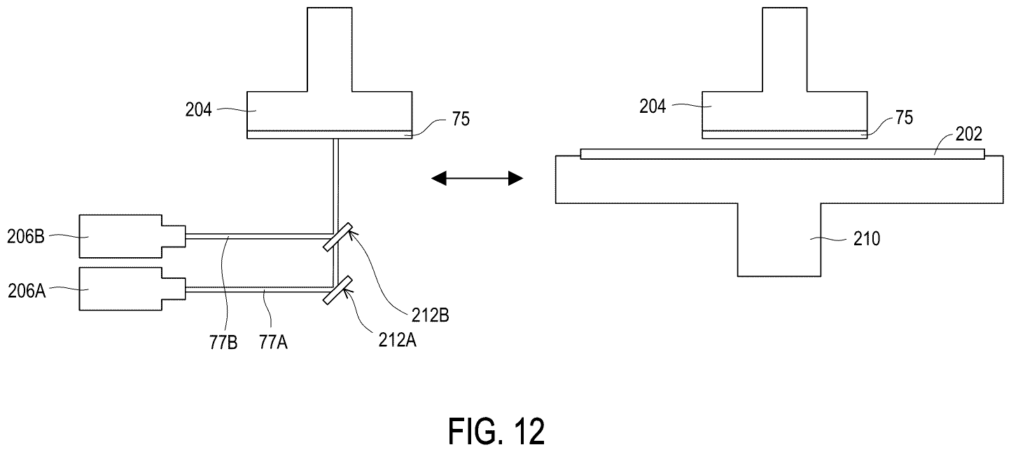

FIG. 12 illustrates a cross-sectional view of the combined laser treatment and planarization apparatus 12 in accordance with some other embodiments. Unless specified otherwise, like reference numerals in this embodiment (and subsequently discussed embodiments) represent like components in the embodiment shown in FIGS. 1 through 11 formed by like processes. Accordingly, the process steps and applicable materials may not be repeated herein.

The combined laser treatment and planarization apparatus 12 of the embodiment shown in FIG. 12 may be similar to the combined laser treatment and planarization apparatus 12 of the embodiment shown in FIG. 8, except that the combined laser treatment and planarization apparatus 12 of the embodiment shown in FIG. 12 comprises a plurality of laser sources 206 (e.g., the laser sources 206A and 206B) that each generate a laser beam 77 (e.g., the laser beam 77A generated from the laser source 206A, and the laser beam 77B generated from the laser source 206B). The laser beam 77A and laser beam 77B may be used to perform the laser treatment 76 and/or the laser treatment 82 on the workpiece 75 as described previously in FIGS. 5A through 6D.

The laser sources 206A and 206B may be disposed on a side of the platen 210. In an embodiment, the laser sources 206A and 206B that generate the laser beams 77A and 77B, respectively, may be disposed on a different platform to the rotatable support 204 and the platen 210. The combined laser treatment and planarization apparatus 12 may comprise a galvanometer mirror 212A and a galvanometer mirror 212B that are used to assist in the scanning by the laser beam 77A and the laser beam 77B, respectively, of the workpiece 75. By controlling the current in the galvanometers, the mirrors 212A and 212B can be precisely positioned to direct the laser beams 77A and 77B, respectively. The rotatable support 204 with the workpiece 75 disposed on it may be positioned on a side of the platen 210 (e.g., not vertically above the platen 210), and the galvanometer mirrors 212A and 212B may be used to direct the laser beams 77A and 77B, respectively, on to the diamond layer 74 of the workpiece 75 to perform the laser treatment 76 and/or the laser treatment 82 that were described previously in FIGS. 5A through 6D. In an embodiment, the laser source 206A may have a higher laser power than the laser source 206B. In an embodiment, the laser source 206A may generate the laser beam 77A having a shorter wavelength than a wavelength of the laser beam 77B that is generated by the laser source 206B. In an embodiment, during the laser treatment 76 and/or the laser treatment 82, the laser beam 77A and the laser beam 77B may be generated sequentially (e.g., at different times). In an embodiment, during the laser treatment 76 and/or the laser treatment 82, wherein the laser beam 77A has a different focus depth from the laser beam 77B, the laser beam 77A and the laser beam 77B may be generated simultaneously.

To perform the thinning process 80 and/or the thinning process 88 (e.g. when the thinning process 80 and the thinning process 88 comprise a CMP process), the rotatable support 204 is positioned vertically above the platen 210. The rotatable support 204 is then moved towards the platen 210 until the polishing pad 202 and the workpiece 75 are in physical contact. Due to the rotational action of the rotatable support 204, the workpiece 75 rotates against the polishing pad 202 which results in the abrasion of materials of the workpiece 75 (e.g., the top portion of the diamond layer 74B as shown in FIG. 6C or the graphite layer 78 as shown in FIG. 5D). In an embodiment, a chemical slurry that may contain abrasive particles and/or chemical agents may be utilized during the thinning process 80 and/or the thinning process 88 to facilitate material removal. In an embodiment, the thinning process 80 may be performed using the combined laser treatment and planarization apparatus 12 after the laser treatment 76 is performed using the combined laser treatment and planarization apparatus 12. Further, the thinning process 88 may be performed using the combined laser treatment and planarization apparatus 12 after the laser treatment 82 is performed using the combined laser treatment and planarization apparatus 12.

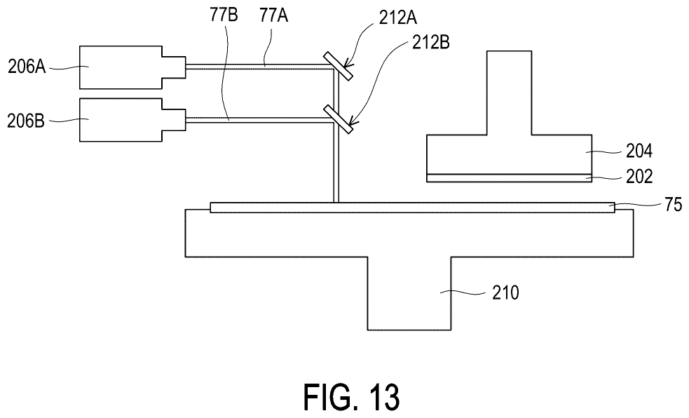

FIG. 13 illustrates a cross-sectional view of the combined laser treatment and planarization apparatus 12 in accordance with some other embodiments. Unless specified otherwise, like reference numerals in this embodiment (and subsequently discussed embodiments) represent like components in the embodiment shown in FIGS. 1 through 12 formed by like processes. Accordingly, the process steps and applicable materials may not be repeated herein.

The combined laser treatment and planarization apparatus 12 of the embodiment shown in FIG. 13 may be similar to the combined laser treatment and planarization apparatus 12 of the embodiment shown in FIG. 9, except that the combined laser treatment and planarization apparatus 12 of the embodiment shown in FIG. 13 comprises a plurality of laser sources 206 (e.g., the laser sources 206A and 206B) that each generate a laser beam 77 (e.g., the laser beam 77A generated from the laser source 206A, and the laser beam 77B generated from the laser source 206B). The laser beam 77A and laser beam 77B may be used to perform the laser treatment 76 and/or the laser treatment 82 on the workpiece 75 as described previously in FIGS. 5A through 6D.

The combined laser treatment and planarization apparatus 12 may comprise the laser sources 206A and 206B disposed above the platen 210 and on a side of the rotatable support 204. The combined laser treatment and planarization apparatus 12 may comprise the galvanometer mirror 212A and the galvanometer mirror 212B that are used to assist in the scanning by the laser beam 77A and the laser beam 77B, respectively, of the workpiece 75. By controlling the current in the galvanometers, the mirrors 212A and 212B can be precisely positioned to direct the laser beams 77A and 77B, respectively, on to the diamond layer 74 of the workpiece 75 to perform the laser treatment 76 and/or the laser treatment 82 that were described previously in FIGS. 5A through 6D. In addition, the platen 210 may be rotated during the laser treatment 76 and/or the laser treatment 82. In an embodiment, the laser source 206A may have a higher laser power than the laser source 206B. In an embodiment, the laser source 206A may generate the laser beam 77A having a shorter wavelength than a wavelength of the laser beam 77B that is generated by the laser source 206B. In an embodiment, during the laser treatment 76 and/or the laser treatment 82, the laser beam 77A and the laser beam 77B may be generated sequentially (e.g., at different times). In an embodiment, during the laser treatment 76 and/or the laser treatment 82, wherein the laser beam 77A has a different focus depth from the laser beam 77B, the laser beam 77A and the laser beam 77B may be generated simultaneously.

To perform the thinning process 80 and/or the thinning process 88 (e.g. when the thinning process 80 and the thinning process 88 comprise a CMP process), the rotatable support 204 is moved vertically towards the platen 210 until the polishing pad 202 and the workpiece 75 are in physical contact. Due to the rotational action of the rotatable support 204 and/or the platen 210, the workpiece 75 rotates against the polishing pad 202 which results in the abrasion of materials of the workpiece 75 (e.g., the top portion of the diamond layer 74B as shown in FIG. 6C or the graphite layer 78 as shown in FIG. 5D). In an embodiment, a chemical slurry that may contain abrasive particles and/or chemical agents may be utilized during the thinning process 80 and/or the thinning process 88 to facilitate material removal. In an embodiment, the laser treatment 76 and the thinning process 80 may be performed simultaneously using the combined laser treatment and planarization apparatus 12. In an embodiment, the thinning process 80 is performed using the combined laser treatment and planarization apparatus 12 after the laser treatment 76 is performed using the combined laser treatment and planarization apparatus 12. In an embodiment, the laser treatment 82 and the thinning process 88 may be performed simultaneously using the combined laser treatment and planarization apparatus 12. In an embodiment, the thinning process 88 is performed using the combined laser treatment and planarization apparatus 12 after the laser treatment 82 is performed using the combined laser treatment and planarization apparatus 12.

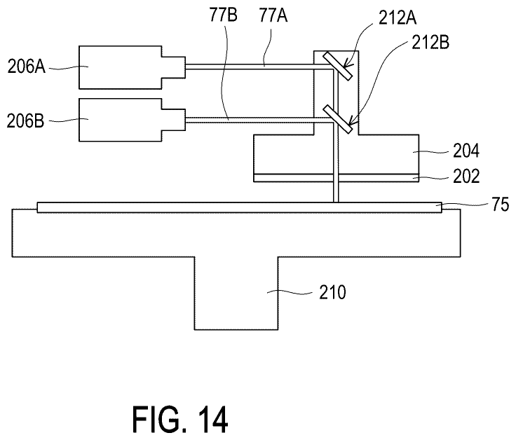

FIG. 14 illustrates a cross-sectional view of the combined laser treatment and planarization apparatus 12 in accordance with some other embodiments. Unless specified otherwise, like reference numerals in this embodiment (and subsequently discussed embodiments) represent like components in the embodiment shown in FIGS. 1 through 13 formed by like processes. Accordingly, the process steps and applicable materials may not be repeated herein.

The combined laser treatment and planarization apparatus 12 of the embodiment shown in FIG. 14 may be similar to the combined laser treatment and planarization apparatus 12 of the embodiment shown in FIG. 10, except that the combined laser treatment and planarization apparatus 12 of the embodiment shown in FIG. 14 comprises a plurality of laser sources 206 (e.g., the laser sources 206A and 206B) that each generate a laser beam 77 (e.g., the laser beam 77A generated from the laser source 206A, and the laser beam 77B generated from the laser source 206B). The laser beam 77A and laser beam 77B may be used to perform the laser treatment 76 and/or the laser treatment 82 on the workpiece 75 as described previously in FIGS. 5A through 6D.

The combined laser treatment and planarization apparatus 12 may comprise the laser sources 206A and 206B disposed vertically above the platen 210 and on a side of the rotatable support 204. The combined laser treatment and planarization apparatus 12 may comprise the galvanometer mirrors 212A and 212B that are used to assist in the scanning by the laser beam 77A and 77B, respectively, of the workpiece 75. By controlling the current in the galvanometers, the mirrors 212A and 212B can be precisely positioned to direct the laser beams 77A and 77B, respectively. The galvanometer mirrors 212A and 212B may be disposed within the structure of the rotatable support 204. In an embodiment, the laser source 206A may have a higher laser power than the laser source 206B. In an embodiment, the laser source 206A may generate the laser beam 77A having a shorter wavelength than a wavelength of the laser beam 77B that is generated by the laser source 206B. In an embodiment, during the laser treatment 76 and/or the laser treatment 82, the laser beam 77A and the laser beam 77B may be generated sequentially (e.g., at different times). In an embodiment, during the laser treatment 76 and/or the laser treatment 82, wherein the laser beam 77A has a different focus depth from the laser beam 77B, the laser beam 77A and the laser beam 77B may be generated simultaneously.

Each of the rotatable support 204 and the polishing pad 202 may comprise a hole that extends vertically through the respective rotatable support 204 and the polishing pad 202, through which the laser beams 77A and 77B can be directed by the galvanometer mirrors 212A and 212B, respectively, and then on to the diamond layer 74 of the workpiece 75 to perform the laser treatment 76 and/or the laser treatment 82 that were described previously in FIGS. 5A through 6D. In an embodiment, the hole that extends through the rotatable support 204 may extend vertically through a center of the rotatable support 204. In an embodiment, the rotatable support 204 and the polishing pad 202 may comprise transparent portions through which the laser beams 77A and 77B can be directed by the galvanometer mirrors 212A and 212B, respectively, and then on to the diamond layer 74 of the workpiece 75 to perform the laser treatment 76 and/or the laser treatment 82 that were described previously in FIGS. 5A through 6D. The transparent portions of the rotatable support 204 and the polishing pad 202 may comprise thermoplastic polyurethane, or the like. In an embodiment, the platen 210 may be rotated during the laser treatment 76 and/or the laser treatment 82.

To perform the thinning process 80 and/or the thinning process 88 (e.g. when the thinning process 80 and the thinning process 88 comprise a CMP process), the rotatable support 204 is moved vertically towards the platen 210 until the polishing pad 202 and the workpiece 75 are in physical contact. Due to the rotational action of the rotatable support 204 and/or the platen 210, the workpiece 75 rotates against the polishing pad 202 which results in the abrasion of materials of the workpiece 75 (e.g., the top portion of the diamond layer 74B as shown in FIG. 6C or the graphite layer 78 as shown in FIG. 5D). In an embodiment, a chemical slurry that may contain abrasive particles and/or chemical agents may be utilized during the thinning process 80 and/or the thinning process 88 to facilitate material removal. In an embodiment, the laser treatment 76 and the thinning process 80 may be performed simultaneously using the combined laser treatment and planarization apparatus 12. In an embodiment, the thinning process 80 is performed using the combined laser treatment and planarization apparatus 12 after the laser treatment 76 is performed using the combined laser treatment and planarization apparatus 12. In an embodiment, the laser treatment 82 and the thinning process 88 may be performed simultaneously using the combined laser treatment and planarization apparatus 12. In an embodiment, the thinning process 88 is performed using the combined laser treatment and planarization apparatus 12 after the laser treatment 82 is performed using the combined laser treatment and planarization apparatus 12.

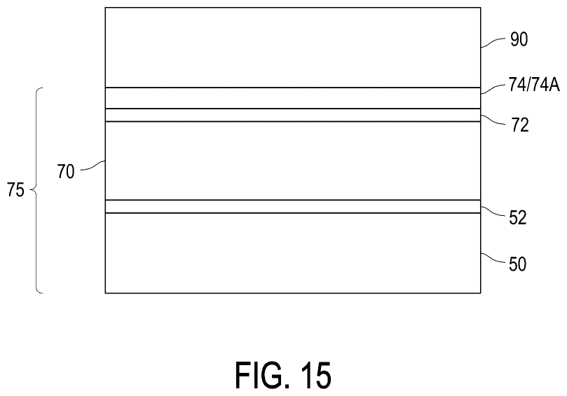

In FIG. 15, a substrate 90 may be bonded to the workpiece 75 after the laser treatment 76 and the thinning process 80 (described previously in FIGS. 5A through 5D) is performed on the workpiece 75. Specifically, the substrate 90 may be bonded to a top surface of the remaining portion of the diamond layer 74. In other embodiments, the substrate 90 may be bonded to the workpiece 75 after the laser treatment 82 and the thinning process 88 (described previously in FIGS. 6A through 6D) is performed on the workpiece 75. Specifically, the substrate 90 may be bonded to a top surface of the bottom portion of the diamond layer 74A.

In an embodiment, the substrate 90 (e.g., a silicon substrate, a silicon wafer, or the like) may be bonded to the top surface of the remaining portion of the diamond layer 74 (e.g., shown in FIG. 5D) or the top surface of the bottom portion of the diamond layer 74A (e.g., shown in FIG. 6C) using a suitable technique such as fusion bonding, or the like. For example, in various embodiments, the substrate 90 may be bonded to the remaining portion of the diamond layer 74 using bonding layers on the respective surfaces of the substrate 90 and the remaining portion of the diamond layer 74. In other embodiments, the substrate 90 may be bonded to the bottom portion of the diamond layer 74A using bonding layers on the respective surfaces of the substrate 90 and the bottom portion of the diamond layer 74A. In some embodiments, the bonding layers (not shown in the Figures) may each comprise silicon oxide that are formed using a deposition process, such as chemical vapor deposition (CVD), physical vapor deposition (PVD), or the like. The bonding layers maybe formed on the surfaces of the substrate 90 and the remaining portion of the diamond layer 74, respectively, or on the surfaces of the substrate 90 and the bottom portion of the diamond layer 74A, respectively.

Prior to bonding, at least one of the bonding layers may be subjected to a surface treatment. The surface treatment may include a plasma treatment. The plasma treatment may be performed in a vacuum environment. After the plasma treatment, the surface treatment may further include a cleaning process (e.g., a rinse with deionized water, or the like) that may be applied to one or both bonding layers. The substrate 90 is then aligned with the workpiece 75 and the two are pressed against each other to bond them together at room temperature (between about 21 degrees and about 25 degrees). The bonding process may be strengthened by a subsequent annealing step. For example, this may be done by heating the substrate 90 and the workpiece 75 to a temperature in a range from 140° C. to 500° C.

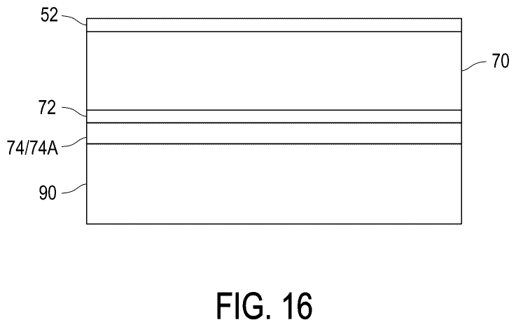

In FIG. 16, the structure shown previously in FIG. 15 may be flipped over. A thinning process is then applied to a top surface of the substrate 50 to remove the substrate 50 and expose the active layer 52. The thinning process may include a grinding process, a chemical mechanical polish (CMP), combination thereof, or the like.

In FIG. 17, a dielectric layer 92 is formed over the active layer 52. In some embodiments, the dielectric layer 92 may be formed using chemical vapor deposition (CVD), atomic layer deposition (ALD), or the like, and may comprise silicon nitride, silicon oxide, or the like.

After the formation of the dielectric layer 92, vias 94 may be formed that extend through the dielectric layer 92. The vias 94 may be formed to electrically connect the one or more devices in the active layer 52 to a subsequently formed back-side interconnect structure 104. To form the vias 94, openings for the vias 94 are formed through the dielectric layer 92. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the dielectric layer 92. The remaining liner and conductive material form the vias 94 in the openings.

After the formation of the dielectric layer 92 and the vias 94, a dielectric layer 96 may be formed over the dielectric layer 92 and the vias 94. In some embodiments, the dielectric layer 96 may be formed using chemical vapor deposition (CVD), atomic layer deposition (ALD), or the like, and may comprise silicon nitride, silicon oxide, or the like. Conductive lines 98 may then be formed in the dielectric layer 96. Forming the conductive lines 98 may include patterning recesses in the dielectric layer 96 using a combination of photolithography and etching processes. For example, recesses are patterned in the dielectric layer 96 using a combination of photolithography and etching processes to expose top surfaces of the vias 94. The conductive lines 98 are then formed by depositing a conductive material over the exposed top surfaces of the vias 94 in the recesses in the dielectric layer 96. In some embodiments, the conductive lines 98 comprise a metal layer, which may be a single layer or a composite layer comprising a plurality of sub-layers formed of different materials. In some embodiments, the conductive lines 98 comprise copper, aluminum, cobalt, tungsten, titanium, tantalum, ruthenium, or the like. An optional diffusion barrier and/or optional adhesion layer may be deposited prior to filling the recesses with the conductive material. Suitable materials for the barrier layer/adhesion layer include titanium, titanium nitride, titanium oxide, tantalum, tantalum nitride, titanium oxide, or the like. The conductive lines 98 may be formed using, for example, CVD, ALD, PVD, plating, or the like. The conductive lines 98 are electrically coupled to the vias 94. A planarization process (e.g., a CMP, a grinding, an etch-back, or the like) may be performed to remove excess portions of the conductive lines 98 formed over the dielectric layer 96. In some embodiments, the conductive lines 98 are back-side power rails, which are conductive lines that electrically connect the one or more devices of the active layer 52 to a reference voltage, a supply voltage, or the like.

After the formation of the dielectric layer 96 and the conductive lines 98, a back-side interconnect structure 104 is then formed on the dielectric layer 96 and the conductive lines 98. The back-side interconnect structure 104 includes dielectric layers 102 and layers of conductive features 100 in the dielectric layers 102. The dielectric layers 102 may include low-k dielectric layers formed of low-k dielectric materials. The dielectric layers 102 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 102 may also include polymer layers.

The conductive features 100 may include conductive lines and vias, which may be formed using damascene processes. The conductive features 100 may include metal lines and metal vias, which includes diffusion barriers and a copper containing material over the diffusion barriers. There may also be aluminum pads over and electrically connected to the metal lines and vias. The conductive features 100 may be electrically connected to the conductive lines 98 and the vias 94.

In FIG. 18, a solder resist 106 is formed over the back-side interconnect structure 104, such as over the conductive features 100 and the dielectric layers 102. Openings may be disposed in the solder resist that expose surfaces of topmost conductive features 100 in a topmost layer of the dielectric layers 102. Under bump metallurgies (UBMs) 108 may be formed in the openings for external connection to the back-side interconnect structure 104. The UBMs 108 may have bump portions on and extending along the major surface of the solder resist 106, and have via portions extending through the openings in the solder resist 106 to physically and electrically couple the back-side interconnect structure 104. The UBMs 108 may be formed of a conductive material such as copper, aluminum, tungsten, silver, and combinations thereof, or the like, deposited by CVD, physical vapor deposition (PVD), or the like.

Referring further to FIG. 18, conductive connectors 110 are formed on the UBMs 108. The conductive connectors 110 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 110 may include a conductive material such as solder, copper, aluminum, gold, nickel, silver, palladium, tin, the like, or a combination thereof. In some embodiments, the conductive connectors 110 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 110 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. The conductive connectors 110 may be used to electrically and physically couple the semiconductor device 10 other external devices (e.g., a package substrate, or the like).

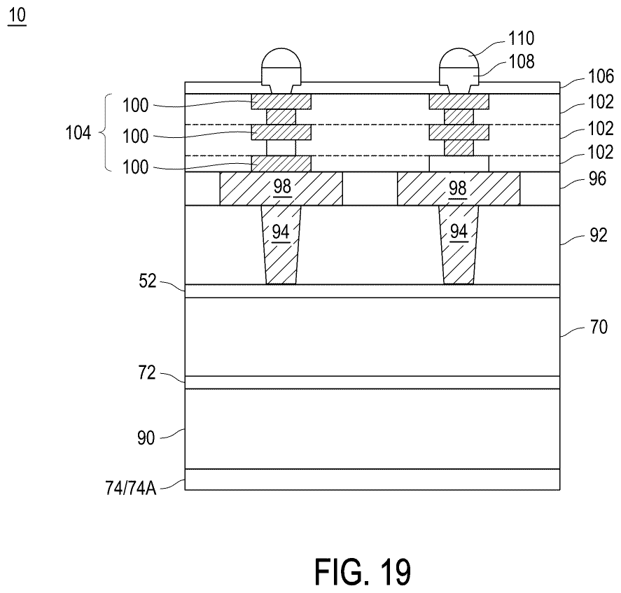

FIG. 19 illustrates a cross-sectional view of the semiconductor device 10 in accordance with some other embodiments. Unless specified otherwise, like reference numerals in this embodiment (and subsequently discussed embodiments) represent like components in the embodiment shown in FIGS. 1 through 18 formed by like processes. Accordingly, the process steps and applicable materials may not be repeated herein. The initial steps of this embodiment are essentially the same as shown in FIGS. 1 through 3.

In FIG. 19, the substrate 90 may be bonded to a top surface of the bonding layer 72. The substrate 90 (e.g., a silicon substrate, a silicon wafer, or the like) may be bonded to the bonding layer 72 using a suitable technique such as fusion bonding, or the like. For example, in various embodiments, the substrate 90 may be bonded to the bonding layer 72 using a bonding layer on a bottom surface of the substrate 90. In some embodiments, the bonding layer (not shown in the Figures) may comprise silicon oxide that is formed using a deposition process, such as chemical vapor deposition (CVD), physical vapor deposition (PVD), or the like, or by a thermal oxidation process.

Prior to bonding, at least one of the bonding layer 72 and the bonding layer on the bottom surface of the substrate 90 may be subjected to a surface treatment. The surface treatment may include a plasma treatment. The plasma treatment may be performed in a vacuum environment. After the plasma treatment, the surface treatment may further include a cleaning process (e.g., a rinse with deionized water, or the like) that may be applied to one or both of the bonding layer 72 and the bonding layer on the bottom surface of the substrate 90. The substrate 90 is then aligned with the bonding layer 72 and the two are pressed against each other to bond them together at room temperature (between about 21 degrees and about 25 degrees). The bonding process may be strengthened by a subsequent annealing step. For example, this may be done by heating the substrate 90 and the bonding layer 72 to a temperature in a range from 140° C. to 500° C.

After the bonding of the substrate 90 to the bonding layer 72, the diamond layer 74 is formed over the substrate 90 using similar materials and processes as were described previously in FIG. 4, such that the diamond layer 74 is disposed on an opposite side of the substrate 90 as the bonding layer 72. After the formation of the diamond layer 74, the laser treatment 76 and the thinning process 80 described previously in FIGS. 5A through 5D may be performed on the diamond layer 74, such that after the laser treatment 76 and the thinning process 80 is performed, the remaining portion of the diamond layer 74 is disposed over the substrate 90. In other embodiments, after the formation of the diamond layer 74, the laser treatment 82 and the thinning process 88 described previously in FIGS. 6A through 6D may be performed on the diamond layer 74, such that after the laser treatment 82 and the thinning process 88 is performed, the bottom portion of the diamond layer 74A is disposed over the substrate 90. After performing the laser treatment 76 and the thinning process 80, or after performing the laser treatment 82 and the thinning process 88, a thinning process is then applied to a surface of the substrate 50 to remove the substrate 50 and expose the active layer 52. The thinning process may include a grinding process, a chemical mechanical polish (CMP), combination thereof, or the like.

After the thinning process to remove the substrate 50 is performed, the vias 94, the conductive lines 98, the dielectric layer 92, the dielectric layer 96, the back-side interconnect structure 104, the solder resist 106, the UBMs 108, and the conductive connectors 110 are formed using similar materials and similar processes as were described previously in FIG. 17 and FIG. 18. The remaining portion of the diamond layer 74 or the bottom portion of the diamond layer 74A may function as a heat dissipation layer that is used to effectively dissipate the heat generated in the active layer 52 and the conductive lines 98.

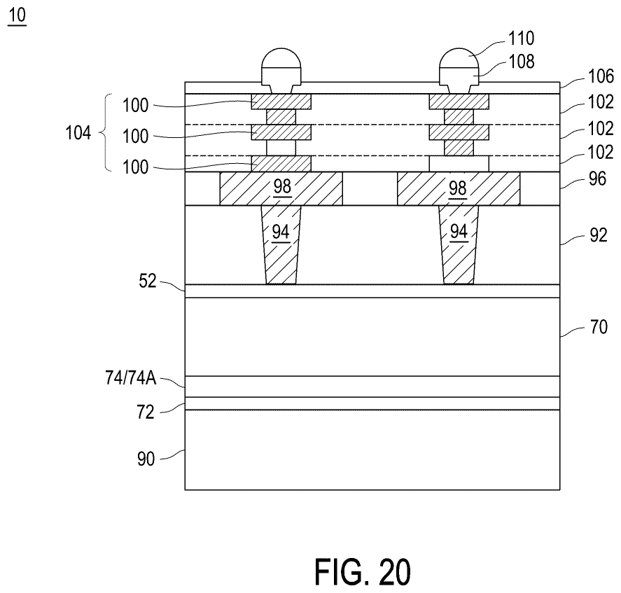

FIG. 20 illustrates a cross-sectional view of the semiconductor device 10 in accordance with some other embodiments. Unless specified otherwise, like reference numerals in this embodiment (and subsequently discussed embodiments) represent like components in the embodiment shown in FIGS. 1 through 19 formed by like processes. Accordingly, the process steps and applicable materials may not be repeated herein. The initial steps of this embodiment are essentially the same as shown in FIGS. 1 through 2.

In FIG. 20, the diamond layer 74 is formed over the structure 70 using similar materials and similar processes as were described previously in FIG. 4. After the formation of the diamond layer 74, the laser treatment 76 and the thinning process 80 described previously in FIGS. 5A through 5D may be performed on the diamond layer 74, such that after the laser treatment 76 and the thinning process 80 is performed, the remaining portion of the diamond layer 74 is disposed over the structure 70. In other embodiments, after the formation of the diamond layer 74, the laser treatment 82 and the thinning process 88 described previously in FIGS. 6A through 6D may be performed on the diamond layer 74, such that after the laser treatment 82 and the thinning process 88 is performed, the bottom portion of the diamond layer 74A is disposed over the structure 70. After performing the laser treatment 76 and the thinning process 80, the bonding layer 72 is formed over the remaining portion of the diamond layer 74 using similar processes and similar materials as were described previously in FIG. 3 for the formation of the bonding layer 72. In other embodiments, after performing the laser treatment 82 and the thinning process 88, the bonding layer 72 is formed over the bottom portion of the diamond layer 74A using similar processes and similar materials as were described previously in FIG. 3 for the formation of the bonding layer 72.

After the formation of the bonding layer 72, the substrate 90 is bonded to a top surface of the bonding layer 72 using similar processes and similar materials as were described previously in FIG. 19 to bond the substrate 90 to the top surface of the bonding layer 72. After bonding the substrate 90 to the top surface of the bonding layer 72, a thinning process is then applied to a surface of the substrate 50 to remove the substrate 50 and expose the active layer 52. The thinning process may include a grinding process, a chemical mechanical polish (CMP), combination thereof, or the like.

After the thinning process to remove the substrate 50 is performed, the vias 94, the conductive lines 98, the dielectric layer 92, the dielectric layer 96, the back-side interconnect structure 104, the solder resist 106, the UBMs 108, and the conductive connectors 110 are formed using similar materials and similar processes as were described previously in FIG. 17 and FIG. 18. The remaining portion of the diamond layer 74 or the bottom portion of the diamond layer 74A may function as a heat dissipation layer that is used to effectively dissipate the heat generated in the active layer 52 and the conductive lines 98.

The embodiments of the present disclosure have some advantageous features. The embodiments include formation of a semiconductor device that includes forming a diamond layer over an active layer (also referred to as a device layer). A laser treatment is then performed in which laser energy is applied to the diamond layer using a laser beam to transform a top portion of the diamond layer into a graphite layer. In other embodiments, the laser treatment is used to modify the top portion of the diamond layer (e.g., to form a modified diamond layer). A planarization process that may include chemical mechanical planarization (CMP) is then performed to remove the graphite layer or the modified diamond layer and leave a remaining portion of the diamond layer over the active layer. The diamond layer may function as a heat dissipation layer. A semiconductor substrate may then be bonded to an opposite side of the remaining portion of the diamond layer as the active layer. These advantages include allowing the removal of the top portion of the diamond layer (in the form of the graphite layer or the modified diamond layer) at higher polishing rates using the planarization process. In addition, the one or more embodiments, can be integrated with existing semiconductor manufacturing processes, which results in optimized efficiency and cost-effectiveness. Further, an improved surface roughness of the remaining portion of the diamond layer can be achieved after the planarization process is performed.

In accordance with an embodiment, a method includes forming a device layer on a first surface of a first substrate; forming a first interconnect structure over the device layer; depositing a bonding layer over the first interconnect structure; forming a diamond layer over the bonding layer; performing a laser treatment on a top portion of the diamond layer by applying laser energy to the top portion of the diamond layer using a laser beam; and performing a thinning process on the diamond layer to remove the top portion of the diamond layer. In an embodiment, during performing the laser treatment, the top portion of the diamond layer is transformed to graphite. In an embodiment, the laser treatment on the top portion of the diamond layer and the thinning process on the diamond layer are performed simultaneously. In an embodiment, the thinning process on the diamond layer is performed after performing the laser treatment on the top portion of the diamond layer. In an embodiment, during performing the laser treatment, the top portion of the diamond layer is modified to induce the formation of cracks and defects in the top portion of the diamond layer. In an embodiment, the laser treatment on the top portion of the diamond layer and the thinning process on the diamond layer are performed simultaneously. In an embodiment, the thinning process on the diamond layer is performed after performing the laser treatment on the top portion of the diamond layer. In an embodiment, performing the thinning process on the diamond layer includes performing a mechanical polishing process or a chemical mechanical planarization (CMP) process on a surface of the diamond layer.

In accordance with an embodiment, a method includes forming a device layer on a first surface of a first substrate; forming a bonding layer over the device layer; forming a diamond layer over the bonding layer; performing a first laser treatment on a top portion of the diamond layer by applying laser energy to the top portion of the diamond layer using a first laser beam having a first laser power; performing a second laser treatment on the top portion of the diamond layer by applying laser energy to the top portion of the diamond layer using a second laser beam having a second laser power, where the first laser power is greater than the second laser power; and planarizing the top portion of the diamond layer to remove the top portion of the diamond layer. In an embodiment, the first laser power and the second laser power are in a range from 10 mJ/cm² to 10 J/cm². In an embodiment, the first laser beam is generated by a first laser source and the second laser beam is generated by a second laser source that is different from the first laser source. In an embodiment, during the first laser treatment and the second laser treatment, the top portion of the diamond layer is transformed into graphite. In an embodiment, after planarizing the top portion of the diamond layer, a remaining portion of the diamond layer has a thickness that is in a range from 100 nm to 10 μm. In an embodiment, after planarizing the top portion of the diamond layer, the remaining portion of the diamond layer has surface roughness that is less than 50 nm. In an embodiment, planarizing the top portion of the diamond layer is performed at the same time as performing the second laser treatment on the top portion of the diamond layer.

In accordance with an embodiment, an apparatus includes a polishing pad disposed on a platen; a rotatable support disposed above the platen, where the rotatable support is configured to support a workpiece, where the platen includes a first hole that extends through the platen, and where the rotatable support is configured to move vertically and initiate physical contact between the polishing pad and the workpiece; a first laser source disposed below the platen, the first laser source configured to generate a first laser beam; and a first galvanometer mirror configured to direct the first laser beam through the first hole in the platen and onto a surface of the workpiece. In an embodiment, the apparatus further includes a second laser source disposed below the platen, the second laser source configured to generate a second laser beam; and a second galvanometer mirror configured to direct the second laser beam through the first hole in the platen and onto the surface of the workpiece. In an embodiment, the first laser source has a first laser power that is higher than a second laser power of the second laser source. In an embodiment, the first laser beam has a first wavelength that is shorter than a second wavelength of the second laser beam. In an embodiment, the first laser source and the second laser source are configured to simultaneously generate the first laser beam and the second laser beam, respectively.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a device layer on a first surface of a first substrate;
forming a first interconnect structure over the device layer;
depositing a bonding layer over the first interconnect structure;
forming a diamond layer over the bonding layer;
performing a laser treatment on a top portion of the diamond layer by applying laser energy to the top portion of the diamond layer using a laser beam; and
performing a thinning process on the diamond layer to remove the top portion of the diamond layer.

2. The method of claim 1, wherein during performing the laser treatment, the top portion of the diamond layer is transformed to graphite.

3. The method of claim 2, wherein the laser treatment on the top portion of the diamond layer and the thinning process on the diamond layer are performed simultaneously.

4. The method of claim 2, wherein the thinning process on the diamond layer is performed after performing the laser treatment on the top portion of the diamond layer.

5. The method of claim 1, wherein during performing the laser treatment, the top portion of the diamond layer is modified to induce the formation of cracks and defects in the top portion of the diamond layer.

6. The method of claim 5, wherein the laser treatment on the top portion of the diamond layer and the thinning process on the diamond layer are performed simultaneously.

7. The method of claim 5, wherein the thinning process on the diamond layer is performed after performing the laser treatment on the top portion of the diamond layer.

8. The method of claim 1, wherein performing the thinning process on the diamond layer comprises performing a mechanical polishing process or a chemical mechanical planarization (CMP) process on a surface of the diamond layer.

9. A method comprising:
forming a device layer on a first surface of a first substrate;
forming a bonding layer over the device layer;
forming a diamond layer over the bonding layer;
performing a first laser treatment on a top portion of the diamond layer by applying laser energy to the top portion of the diamond layer using a first laser beam having a first laser power;
performing a second laser treatment on the top portion of the diamond layer by applying laser energy to the top portion of the diamond layer using a second laser beam having a second laser power, wherein the first laser power is greater than the second laser power; and
planarizing the top portion of the diamond layer to remove the top portion of the diamond layer.

10. The method of claim 9, wherein the first laser power and the second laser power are in a range from 10 mJ/cm² to 10 J/cm².

11. The method of claim 10, wherein the first laser beam is generated by a first laser source and the second laser beam is generated by a second laser source that is different from the first laser source.

12. The method of claim 9, wherein during the first laser treatment and the second laser treatment, the top portion of the diamond layer is transformed into graphite.

13. The method of claim 9, wherein after planarizing the top portion of the diamond layer, a remaining portion of the diamond layer has a thickness that is in a range from 100 nm to 10 μm.

14. The method of claim 13, wherein after planarizing the top portion of the diamond layer, the remaining portion of the diamond layer has surface roughness that is less than 50 nm.

15. The method of claim 9, wherein planarizing the top portion of the diamond layer is performed at the same time as performing the second laser treatment on the top portion of the diamond layer.

16. An apparatus comprising:
a polishing pad disposed on a platen;
a rotatable support disposed above the platen, wherein the rotatable support is configured to support a workpiece, wherein the platen comprises a first hole that extends through the platen, and wherein the rotatable support is configured to move vertically and initiate physical contact between the polishing pad and the workpiece;
a first laser source disposed below the platen, the first laser source configured to generate a first laser beam; and
a first galvanometer mirror configured to direct the first laser beam through the first hole in the platen and onto a surface of the workpiece.

17. The apparatus of claim 16, further comprising:
a second laser source disposed below the platen, the second laser source configured to generate a second laser beam; and
a second galvanometer mirror configured to direct the second laser beam through the first hole in the platen and onto the surface of the workpiece.

18. The apparatus of claim 17, wherein the first laser source has a first laser power that is higher than a second laser power of the second laser source.

19. The apparatus of claim 17, wherein the first laser beam has a first wavelength that is shorter than a second wavelength of the second laser beam.

20. The apparatus of claim 17, wherein the first laser source and the second laser source are configured to simultaneously generate the first laser beam and the second laser beam, respectively.
